(19) United States
(12) Patent Application Publication
(10) Pub. No.: US 2008/0237832 A1
(43) Pub. Date: Oct. 2, 2008

(54) MULTI-CHIP SEMICONDUCTOR PACKAGE STRUCTURE

(75) Inventors: Shih-Ping Hsu, Hsin-Chu (TW); Chung-Cheng Lien, Hsin-Chu (TW); Chia-Wei Chang, Hsin-Chu (TW)

Correspondence Address: PEARNE & GORDON LLP, 1801 EAST 9TH STREET, SUITE 1200, CLEVELAND, OH, 44114-3108, US

(73) Assignee: PHOENIX PRECISION TECHNOLOGY CORPORATION, Hsin-Chu (TW)

(21) Appl. No.: 12/047,810

(22) Filed: Mar. 13, 2008

(30) Foreign Application Priority Data
Mar. 27, 2007 (TW) 096110457

(51) Int. Cl. H01L 23/49

(52) U.S. Cl. 257/691; 257/E23.024

(57) ABSTRACT

A multi-chip semiconductor package structure is disclosed, including a carrier board having a first and an opposing second surfaces and formed with at least an opening penetrating the first and second surfaces, wherein a plurality of electrically connecting pads are formed on the first and second surfaces of the carrier board, respectively; a semiconductor component disposed in the opening, the semiconductor component having a first and a second active surfaces each with a plurality of electrode pads being formed thereon; a third semiconductor chip having an active surface and an inactive surface, the active surface having a plurality of electrode pads formed thereon for electrically connecting with the electrically connecting pads on the first surface of the carrier board and the electrode pads on the first active surface of the semiconductor component; and a fourth semiconductor chip having an active surface and an inactive surface, the active surface having a plurality of electrode pads formed thereon for electrically connecting with the electrically connecting pads on the second surface of the carrier board and the electrode pads on the second active surface of the semiconductor component, thereby providing a modularized structure for electrically connecting with other modules or stack devices and enhancing electrical functionality.

### BACKGROUND OF THE INVENTION

1. Field of the Invention

The present invention relates generally to packages, and more particularly, to a multi-chip semiconductor package structure.

2. Description of Related Art

Owing to the evolution of semiconductor package technologies, a great variety of packaging models of semiconductor devices have been developed. A traditional semiconductor device mainly has a package substrate or a lead frame, thereon a semiconductor component, such as an integrated circuit, is mounted, and then the semiconductor component is electrically connected to the package substrate or the lead frame before proceeding to an encapsulation process with encapsulant. To fit in with the trend of miniaturization, high memory storage capacity, and high speed of electronic products by increasing electricity functions of semiconductor components and fulfilling the goal of high integration and miniaturization of semiconductor packages as well as enhancing the performance and memory storage capacity of a single semiconductor package, most known semiconductor packages have multiple chips packaged by multi chip module (MCM). The MCM packages are characterized by reduced overall volume and enhanced electricity functions and thus have become mainstream packages, wherein at least two semiconductor chips are mounted on a chip carrier of a single package, and each of the semiconductor chips is mounted on the carrier by being stacked up; this sort of packaging structure of stacked chips has been disclosed in U.S. Pat. No. 6,798,049.

As shown in FIG. 1, which is a cross-sectional view of a semiconductor package according to U.S. Pat. No. 6,798,049, the essential features disclosed in U.S. Pat. No. 6,798,049 are: an opening 101 formed in a circuit board 10; a circuit layer 11, which has electrically connecting pads 11a and wire bonding pads 11b, is formed on at least one surface of the circuit board 10; two semiconductor chips 121 and 122 stacked and integrated together inside the opening 101, wherein the two semiconductor chips 121 and 122 are electrically connected to each other with a bonding layer 13 in between; the semiconductor chip 122 is electrically connected to the wire bonding pads 11b on the circuit layer 11 via conductive elements 14, such as gold wires, and then the opening 101 of the circuit board 10 is filled with encapsulant 15 to encapsulate the semiconductor chips 121 and 122 as well as the conductive elements 14; a solder mask 16 is formed on the circuit layer 11 of the circuit board 10, and then a plurality of openings 16a are formed in the solder mask 16 to expose the electrically connecting pads 11a, and also a conductive element 17, such as a solder ball, is formed on each opening 16a of the solder mask 16; a packaging process is completed thus.

However, the two semiconductor chips 121 and 122 require the bonding layer 13 of chip scale connection in between to electrically connect to each other. In other words, the semiconductor chips 121 and 122 need a pre-stacking process of electrical connection in a chip fabrication plant before being delivered to a packaging plant for packaging, thus the fabrication process is more complicated, and in consequence the production cost is high.

In the case of a chip stacking process intended for enhancement of electricity functions and multi chip module performance, additional enhancement requires additional stacking which, however, increases complexity of the circuit layer 11, not to mention that the amount of wire bonding pads 11b of the circuit layer 11 must be increased. To increase the amount of wire bonding pads 11b and circuit density in a limited or fixed usable area, the circuit board for carrying the semiconductor chips 121 and 122 must have fine lines in order to meet the requirement for compact packages.

However, fine circuit lines have a limited effect on reducing required circuit board area. In the case of directly stacking up semiconductor chips 121 and 122 for increasing electrical functions and multi-chip module performances, electrical functions and multi-chip module performances cannot be continuously expanded because the amount of stackable chips is limited.

Hence, the circuit board manufacturing sector is faced with an urgent issue that involves providing a package structure capable of effectively increasing density of multi-chip modules mounted on a circuit board of multi-layers, decreasing the required area on the circuit board of multi-layers for mounting semiconductor chips, achieving the goal to reduce package size, and consequently enhancing memory storage capacity.

### SUMMARY OF THE INVENTION

In view of the disadvantages of the prior art mentioned above, it is a primary objective of the present invention to provide a multi-chip semiconductor package structure capable of stacking up multiple chips as well as enhancing electricity abilities of the package structure.

It is another objective of the present invention to provide a multi-chip semiconductor package structure capable of simplifying a fabrication process as well as reducing cost.

It is a further objective of the present invention to provide a multi-chip semiconductor package structure capable of stacking up with other electronic devices, as well as enhancing and expanding electricity abilities.

In order to attain the above and other objectives, the present invention discloses a multi-chip semiconductor package structure which comprises: a carrier board having a first surface and a second surface and formed with at least an opening penetrating the first and second surfaces, a plurality of electrically connecting pads being formed on the first and second surfaces of the carrier board; a semiconductor component disposed in the opening, wherein the semiconductor component has a first and a second active surfaces each with a plurality of electrode pads formed thereon; a third semiconductor chip having an active surface and an inactive surface, wherein a plurality of electrode pads are formed on the active surface of the third semiconductor chip for electrically connecting the electrically connecting pads on the first surface of the carrier board and the electrode pads on the first active surface of the semiconductor component; and a fourth semiconductor chip having an active surface and an inactive surface, wherein a plurality of electrode pads are formed on the active surface of the fourth semiconductor chip for electrically connecting the electrically connecting pads on the second surface of the carrier board and the electrode pads on the second active surface of the semiconductor component.

The carrier board is implemented as a single circuit board or a combination of a plurality of circuit boards. The first conductive elements are metal wires. The semiconductor component is fixed in position in the opening by an adhesive material.

The semiconductor component comprises a first and a second semiconductor chips each having an active surface with a plurality of electrode pads and an inactive surface, allowing the first and second semiconductor chips to be bonded together by coupling of the inactive surfaces thereof, such that the active surfaces of the first and second semiconductor chips are exposed to form the first and second active surfaces of the semiconductor component. A bonding material is formed on the inactive surfaces of the first and second semiconductor chips for bonding together the first and second semiconductor chips. The bonding material can be a UV (Ultra Violet) paste or an epoxy resin.

The multi-chip semiconductor package structure further comprises a plurality of first conductive elements such as solder balls formed between the electrically connecting pads of the carrier board and the electrode pads of the third and fourth semiconductor chips for electrically connecting the carrier board to the third and fourth semiconductor chips as well as formed between the electrode pads of the semiconductor component and the electrode pads of the third and fourth semiconductor chips for electrically connecting the semiconductor component to the third and fourth semiconductor chips.

A plurality of second conductive elements are further formed on a portion of the electrically connecting pads, wherein the portion of the electrically connecting pads are formed on the second surface of the carrier board but not electrically connected to the fourth semiconductor chip. The second conductive elements can be solder balls, pins or metal pads.

The multi-chip semiconductor package structure further comprises a stack device electrically connected, via a plurality of third conductive elements, to a portion of the electrically connecting pads formed on the first surface of the carrier board but not electrically connected to the third semiconductor chip. The stack device is a flip chip package structure, a wire bonding package structure, or a chip embedded package structure.

The present invention discloses bonding together a first and a second semiconductor chips to form a semiconductor component by coupling of inactive surfaces of the first and second semiconductor chips, such that the semiconductor component is provided with exposed first and second active surfaces. The semiconductor component is embedded in an opening of a carrier board. A third and a fourth semiconductor chips are electrically connected to the carrier board so as to enhance the electrical function and solve known problems such as connection complexity and high cost resulted from chip stacking. Moreover, the electrical function of the carrier board embedded with the semiconductor component can be enhanced and expanded by stacking and electrically connecting a stack device to the carrier board.

### BRIEF DESCRIPTION OF DRAWINGS

FIG. 1 is a cross-sectional view of a multi-chip module semiconductor package structure disclosed by U.S. Pat. No. 6,798,049;

FIGS. 2A to 2G are cross-sectional views showing a fabrication method of a multi-chip semiconductor package structure according to the present invention; and

FIG. 3 is a cross-sectional view showing stack structure of the multi-chip semiconductor package structure according to the present invention.

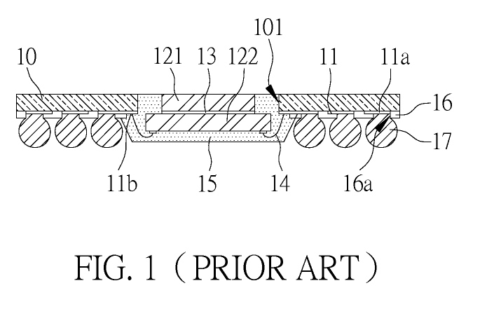

### DETAILED DESCRIPTION OF THE PREFERRED EMBODIMENT

The following illustrative embodiment is provided to illustrate the disclosure of the present invention, these and other advantages and effects can be apparent to those skilled in the art after reading the disclosure of this specification.

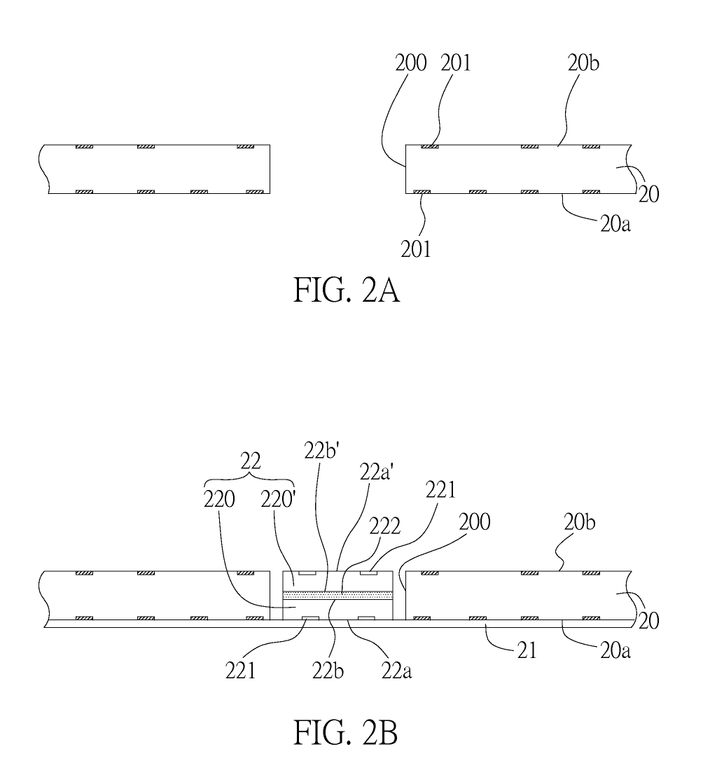

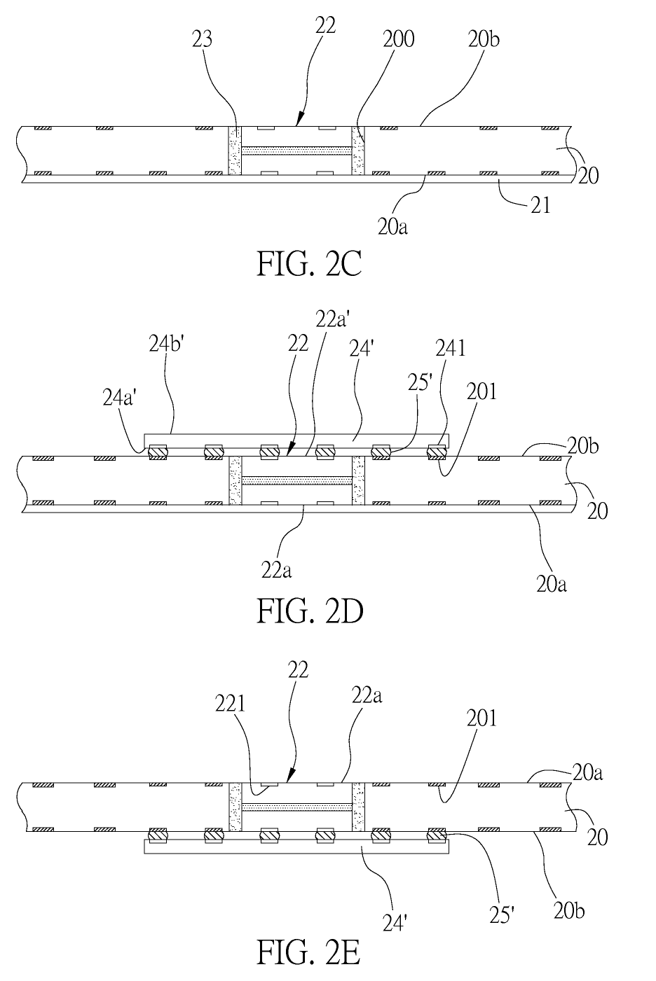

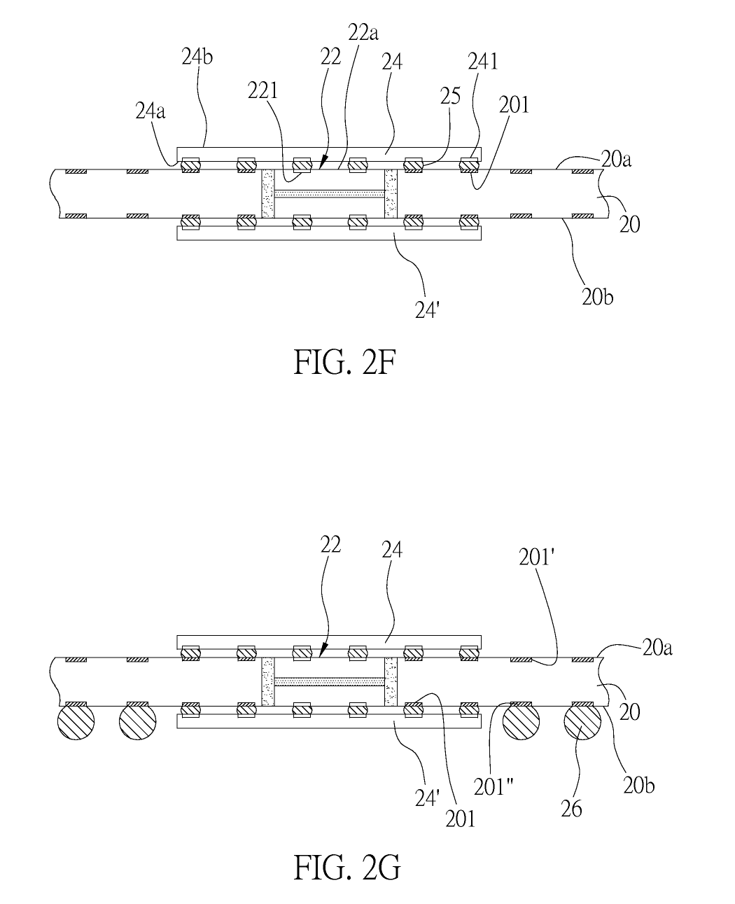

FIGS. 2A to 2G are cross-sectional views showing a fabrication method of a multi-chip semiconductor package structure according to the present invention.

As shown in FIG. 2A, a carrier board 20 having a first surface 20a and a second surface 20b and at least an opening 200 penetrating the first surface 20a and the second surface 20b is provided. A plurality of electrically connecting pads 201 are formed on the first surface 20a and the second surface 20b of the carrier board 20. The carrier board 20 is implemented as a single circuit board or a combination of a plurality of circuit boards.

As shown in FIG. 2B, a release film 21 is formed on the first surface 20a of the carrier board 20 so as to seal one end of the opening 200, and a semiconductor component 22 is disposed in the opening 200 on surface of the release film 21. The semiconductor component 22 has a first active surface 22a and a second active surface 22a′ each having a plurality of electrode pads 221 formed thereon. The semiconductor component 22 comprises a first semiconductor chip 220 and a second semiconductor chip 220′. The first semiconductor chip 220 has an active surface 22a with a plurality of electrode pads 221 formed thereon and an inactive surface 22b; the second semiconductor chip 220′ has an active surface 22a′ with a plurality of electrode pads 221 formed thereon and an inactive surface 22b′. A bonding material 222 is formed between the inactive surfaces 22b, 22b′ of the first and second semiconductor chips 220, 220′ so as to bond together the first and second semiconductor chips 220, 220′ to form the semiconductor component 22. The active surfaces of the first and second semiconductor chips 220, 220′ are exposed to form the first active surface 22a and the second active surface 22a′ of the semiconductor component 22 respectively. The bonding material can be a UV (Ultra Violet) paste or an epoxy resin, wherein the UV paste can be cured by the cross-linking reaction upon being exposed to UV.

The first and second semiconductor chips 220, 220′ can be bonded together by the bonding material 222 after the wafers respectively comprising the first and second semiconductor chips 220, 220′ are singulated. Alternatively, the wafers respectively comprising the first and second semiconductor chips 220, 220′ can be bonded together by the bonding material 222 first and then singulated to form the semiconductor component 22.

As shown in FIG. 2C, an adhesive material 23 is formed in the spacing between the opening 200 of the carrier board 20 and the semiconductor component 22 so as to fix the semiconductor component 22 in position in the opening 200.

As shown in FIG. 2D, a fourth semiconductor chip 24′ electrically connects the second surface 20b of the carrier board 20 and the semiconductor component 22. The fourth semiconductor chip 24′ has an active surface 24a′ with a plurality of electrode pads 241 formed thereon and an inactive surface 24b′. The electrode pads 241 are electrically connected to the electrically connecting pads 201 on the second surface 20b of the carrier board 20 and the electrode pads 221 on the second active surface 22a′ of the semiconductor component 22 via a plurality of first conductive elements 25′ such as solder balls. As shown in FIG. 2E, the carrier board 20 is turned over so that the first surface 20a of the carrier board 20 faces up. Then, the release film 21 is removed to expose the electrically connecting pads 201 on the first surface 20a of the carrier board 20 and the electrode pads 221 on the first active surface 22a of the semiconductor component 22.

As shown in FIG. 2F, a third semiconductor chip 24 electrically connects the first surface 20a of the carrier board 20 and the semiconductor component 22. The third semiconductor chip 24 has an active surface 24a with a plurality of electrode pads 241 formed thereon and an inactive surface 24b. The electrode pads 241 are electrically connected to the electrically connecting pads 201 on the first surface 20a of the carrier board 20 and the electrode pads 221 on the first active surface 22a of the semiconductor component 22 via a plurality of first conductive elements 25.

As shown in FIG. 2G, a plurality of second conductive elements 26 are further formed on electrically connecting pads 201″ on the second surface 20b of the carrier board 20, wherein the electrically connecting pads 201″ are not electrically connected to the fourth semiconductor chip 24′. The second conductive elements 26 can be solder balls, pins, or metal pads for electrical connection with other electronic devices. Thus, a multi-chip semiconductor package structure according to the present invention is obtained.

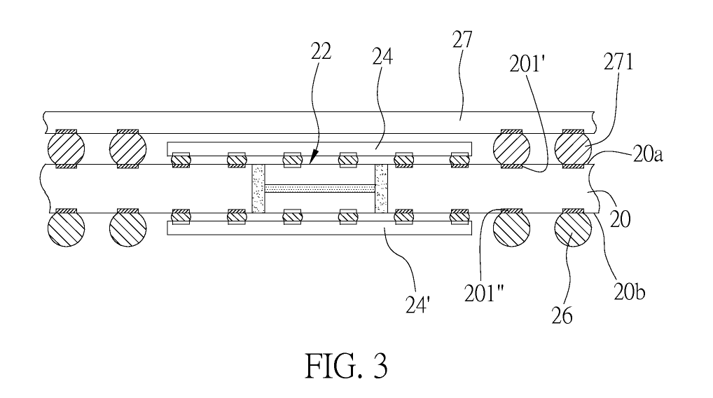

Further referring to FIG. 3, a cross-sectional view of a stack structure of the multi-chip semiconductor package structure is shown. Electrically connecting pads 201′ formed on the first surface 20a of the carrier board 20 but not electrically connected to the third semiconductor chip 24 are electrically connected to a stack device 27 via a plurality of third conductive elements 271. The stack device 27 can be a flip-chip package structure, a wire bonding package structure, or a chip embedded package structure, which can expand the electrical function of the carrier board 20 embedded with the semiconductor component 22.

Therefore, the multi-chip semiconductor package structure according to the present invention comprises: a carrier board 20 having a first surface 20a and a second surface 20b and at least an opening 200 penetrating the first surface 20a and the second surface 20b, the first and second surfaces 20a, 20b of the carrier board 20 each being formed with a plurality of electrically connecting pads 201; a semiconductor component 22 disposed in the opening 200, the semiconductor component 22 having a first active surface 22a and a second active surface 22a′ each being formed with a plurality of electrode pads 221; a third semiconductor chip 24 having an active surface 24a with a plurality of electrode pads 241 and an inactive surface 24b, the electrode pads 241 electrically connecting the electrically connecting pads 201 on the first surface 20a of the carrier board 20 and the electrode pads 221 on the first active surface 22a of the semiconductor component 22; and a fourth semiconductor chip 24′ having an active surface 24a′ with a plurality of electrode pads 241 and an inactive surface 24b′, the electrode pads 241 electrically connecting the electrically connecting pads 201 on the second surface 20b of the carrier board 20 and the electrode pads 221 on the second active surface 22b of the semiconductor component 22.

The carrier board 20 is implemented as a single circuit board or a combination of a plurality of circuit boards. The semiconductor component 22 is fixed in position in the opening 200 of the carrier board 20 by an adhesive material 23.

The semiconductor component 22 comprises a first semiconductor chip 220 and a second semiconductor chip 220′. The first semiconductor chip 220 has an active surface 22a with a plurality of electrode pads 221 and an inactive surface 22b. The second semiconductor chip 220′ has an active surface 22a′ with a plurality of electrode pads 221 and an inactive surface 22b′. The first and second semiconductor chips 220, 220′ are bonded together by a bonding material 222 formed between the inactive surfaces 22b, 22b′ of the first and second semiconductor chips 220, 220′, such that the active surfaces of the first and second semiconductor chips 220, 220′ are exposed to form the first active surface 22a and the second active surface 22a′ of the semiconductor component 22. The bonding material 222 is a UV paste or an epoxy resin.

The electrode pads 241 on the active surfaces 24a, 24a′ of the third and fourth semiconductor chips 24, 24′ are electrically connected to the electrically connecting pads 201 on the first and second surfaces 20a, 20b of the carrier board 20 and the electrode pads 221 on the first and second active surfaces 22a, 22a′ of the semiconductor component 22 via the first conductive elements 25, 25′, such as solder balls, respectively.

The second conductive elements 26 are further formed on the electrically connecting pads 201″ on the second surface 20b of the carrier board 20, wherein the electrically connecting pads 201″ are not electrically connected to the fourth semiconductor chip 24′. The second conductive elements 26 can be solder balls, pins or metal pads. Electrically connecting pads 201′ formed on the first surface 20a of the carrier board 20 but not electrically connected to the third semiconductor chip 24 are electrically connected to a stack device 27 via the third conductive elements 271. The stack device 27 can be a flip-chip package structure, a wire bonding package structure or a chip-embedded package structure.

The present invention discloses bonding together a first and a second semiconductor chips to form a semiconductor component by coupling of inactive surfaces of the first and second semiconductor chips, such that the semiconductor component has a first and a second active surfaces. The semiconductor component having the first and second active surfaces is embedded in an opening of a carrier board. A third and a fourth semiconductor chips are electrically connected to the carrier board so as to enhance the electrical function and solve known problems such as connection complexity and high cost resulted from chip stacking. Further, the electrical function of the carrier board embedded with the semiconductor component can be enhanced and expanded by stacking and electrically connecting a stack device to the carrier board.

The above-described descriptions of the detailed embodiment are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A multi-chip semiconductor package structure, comprising:
a carrier board having a first surface and a second surface and formed with at least an opening penetrating the first and second surfaces, wherein a plurality of electrically connecting pads are formed on the first and second surfaces of the carrier board;
a semiconductor component disposed in the opening, wherein the semiconductor component has a first active surface and a second active surface, the first and second active surfaces are each formed with a plurality of electrode pads thereon;
a third semiconductor chip having an active surface and an inactive surface, wherein a plurality of electrode pads are formed on the active surface of the third semiconductor chip and electrically connected to the electrically connecting pads on the first surface of the carrier board and the electrode pads on the first active surface of the semiconductor component; and
a fourth semiconductor chip having an active surface and an inactive surface, wherein a plurality of electrode pads are formed on the active surface of the fourth semiconductor chip and electrically connected to the electrically connecting pads on the second surface of the carrier board and the electrode pads on the second active surface of the semiconductor component.

2. The multi-chip semiconductor package structure of claim 1, wherein the carrier board is one of a single circuit board and a combination of a plurality of circuit boards.

3. The multi-chip semiconductor package structure of claim 1, wherein the semiconductor component comprises a first and a second semiconductor chips each having an active surface with a plurality of electrode pads and an inactive surface, allowing the first and second semiconductor chips to be bonded together by coupling of the inactive surfaces thereof, such that the active surfaces of the first and second semiconductor chips are exposed to form the first and second active surfaces of the semiconductor component respectively.

4. The multi-chip semiconductor package structure of claim 3, further comprising a bonding material formed on the inactive surfaces of the first and second semiconductor chips and adapted to bond the first and second semiconductor chips together to form the semiconductor component.

5. The multi-chip semiconductor package structure of claim 4, wherein the bonding material is one of a UV (Ultra Violet) paste and an epoxy resin.

6. The multi-chip semiconductor package structure of claim 1, wherein the semiconductor component is fixed in position in the opening by an adhesive material.

7. The multi-chip semiconductor package structure of claim 1, further comprising a plurality of first conductive elements formed between the electrically connecting pads of the carrier board and the electrode pads of the third and fourth semiconductor chips to electrically connect the carrier board to the third and fourth semiconductor chips, as well as formed between the electrode pads of the semiconductor component and the electrode pads of the third and fourth semiconductor chips to electrically connect the semiconductor component to the third and fourth semiconductor chips.

8. The multi-chip semiconductor package structure of claim 7, wherein the first conductive elements are solder balls.

9. The multi-chip semiconductor package structure of claim 1, wherein a plurality of second conductive elements are further formed on a portion of the electrically connecting pads, the portion of the electrically connecting pads being formed on the second surface of the carrier board but not being electrically connected to the fourth semiconductor chip.

10. The multi-chip semiconductor package structure of claim 9, wherein each of the second conductive elements is one of a solder ball, a pin, and a metal pad.

11. The multi-chip semiconductor package structure of claim 1, further comprising a stack device electrically connected, via a plurality of third conductive elements, to a portion of the electrically connecting pads formed on the first surface of the carrier board but not electrically connected to the third semiconductor chip.

12. The multi-chip semiconductor package structure of claim 11, wherein the stack device is one of a flip chip package structure, a wire bonding package structure, and a chip embedded package structure.
